(19) United States
(12) Patent Application Publication
(10) Pub. No.: US 2022/0200026 A1
(43) Pub. Date: Jun. 23, 2022

(54) OUTPUT VOLTAGE PREDICTION SYSTEM AND PREDICTION METHOD FOR FUEL CELL

(71) Applicant: TOYOTA JIDOSHA KABUSHIKI KAISHA, Toyota-shi (JP)

(72) Inventors: Keiji KISHIDA, Toyoake-shi (JP); Michito NORIMOTO, Miyoshi-shi (JP); Kanji INOKO, Toyota-shi (JP); Ayuka OHTA, Toyota-shi (JP)

(21) Appl. No.: 17/412,484

(22) Filed: Aug. 26, 2021

(30) Foreign Application Priority Data
Dec. 18, 2020 (JP) 2020-209926

(51) Int. Cl. H01M 8/04537; H01M 8/04992

(52) U.S. Cl. CPC H01M 8/04552; H01M 2250/20; H01M 8/04582; H01M 8/04992

(57) ABSTRACT

An output voltage prediction system for a fuel cell includes: a storage unit that stores a relationship between a logarithm of a cumulative deterioration index amount and an output voltage of the fuel cell when an output current of the fuel cell is within a predetermined current range, the cumulative deterioration index amount being a cumulative amount of a deterioration index amount related to progress of deterioration of the fuel cell; an input data acquisition unit that acquires the cumulative deterioration index amount of the fuel cell as input data; and a prediction unit that converts the input data acquired by the input data acquisition unit into a logarithm and predicts the output voltage of the fuel cell based on the logarithm of the input data and the relationship stored in the storage unit.

### CROSS-REFERENCE TO RELATED APPLICATION

This application claims priority to Japanese Patent Application No. 2020-209926 filed on Dec. 18, 2020, incorporated herein by reference in its entirety.

### BACKGROUND

### 1. Technical Field

The present disclosure relates to an output voltage prediction system and a prediction method for a fuel cell.

### 2. Description of Related Art

Japanese Unexamined Patent Application Publication No. 2018-147850 (JP 2018-147850 A) describes a technique in which a gradient value of a drive voltage of a pump that supplies fuel gas to a fuel cell with respect to a usage period of the pump is obtained by measuring the drive voltage of the pump a plurality of times, and the drive voltage of the pump after an elapse of a predetermined period is predicted using the gradient value.

### SUMMARY

Although the above-mentioned document describes a technique for predicting the drive voltage of the pump, the document does not describe a technique for predicting an output voltage of the fuel cell. Even when the technique described in the above-mentioned document is directly applied to the technique for predicting the output voltage of the fuel cell and the output voltage of the fuel cell is predicted using the gradient value of the output voltage with respect to the usage period of the fuel cell, there may be a case where the output voltage may not be predicted accurately.

The present disclosure can be implemented in the following aspects.
(1) An aspect of the present disclosure provides an output voltage prediction system for a fuel cell. The output voltage prediction system includes: a storage unit that stores a relationship between a logarithm of a cumulative deterioration index amount and an output voltage of the fuel cell when an output current of the fuel cell is within a predetermined current range, the cumulative deterioration index amount being a cumulative amount of a deterioration index amount related to progress of deterioration of the fuel cell; an input data acquisition unit that acquires the cumulative deterioration index amount of the fuel cell as input data; and a prediction unit that converts the input data acquired by the input data acquisition unit into a logarithm and predicts the output voltage of the fuel cell based on the logarithm of the input data and the relationship stored in the storage unit.

According to the output voltage prediction system of this aspect, in the case where the fuel cell has a characteristic in which the relationship between the logarithm of the cumulative deterioration index amount and the output voltage when the output current of the fuel cell is within the predetermined range is linear, the output voltage of the fuel cell can be predicted accurately.
(2) In the output voltage prediction system of the above aspect, the deterioration index amount may be any one of an operating time of the fuel cell, the number of times of turning on and off power generation of the fuel cell, and the number of fluctuations in the output voltage of the fuel cell.

According to the output voltage prediction system of this aspect, the output voltage of the fuel cell can be predicted accurately using any one of the cumulative amount of the operating time of the fuel cell, the cumulative amount of the number of times of turning on and off the power generation of the fuel cell, and the cumulative amount of the number of fluctuations in the output voltage of the fuel cell as the input data.
(3) In the output voltage prediction system of the above aspect, the current range may be a range in which a ratio of activation overvoltage to overvoltage of the fuel cell exceeds 50%. According to the output voltage prediction system of this aspect, when the ratio of the activation overvoltage to the overvoltage of the fuel cell is large, the relationship between the logarithm of the cumulative deterioration index amount of the fuel cell and the output voltage tends to be linear. Therefore, the output voltage of the fuel cell can be predicted accurately.
(4) The output voltage prediction system of the above aspect may further include: a data acquisition unit that acquires time-series data in which the deterioration index amount or the cumulative deterioration index amount of the fuel cell, the output current of the fuel cell, and the output voltage of the fuel cell are represented in time series; and a relationship generation unit that generates the relationship using the time-series data and stores the relationship in the storage unit.

According to the output voltage prediction system of this aspect, the relationship between the logarithm of the cumulative deterioration index amount of the fuel cell and the output voltage of the fuel cell can be generated using the time-series data acquired by the data acquisition unit.
(5) In the output voltage prediction system of the above aspect, the relationship generation unit may generate the relationship by machine learning.

According to the output voltage prediction system of this aspect, the prediction accuracy of the output voltage of the fuel cell can be enhanced.
(6) In the output voltage prediction system of the above aspect, the fuel cell may supply electric power to a traction motor of a fuel cell vehicle.

According to the output voltage prediction system of this aspect, the relationship between the logarithm of the cumulative deterioration index amount and the output voltage tends to be linear for the fuel cell mounted on the fuel cell vehicle. Therefore, the output voltage of the fuel cell mounted on the fuel cell vehicle can be predicted accurately.

The present disclosure can also be realized in various modes other than the output voltage prediction system for the fuel cell. For example, the present disclosure can be realized in the modes of a deterioration prediction system for the fuel cell, an output voltage prediction method for the fuel cell, a deterioration prediction method for the fuel cell, or the like.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an explanatory view schematically showing a configuration of an output voltage prediction system according to a first embodiment;

FIG. 2 is a block diagram showing a configuration of the output voltage prediction system according to the first embodiment;

FIG. 3 is an explanatory diagram showing a relationship between a current density of a single cell of a fuel cell and overvoltage;

FIG. 4 is a flowchart showing the contents of a learning process in the first embodiment;

FIG. 5 is an explanatory diagram schematically showing time-series data before and after a logarithmic conversion process;

FIG. 6 is an explanatory diagram schematically showing time-series data before and after a filtering process;

FIG. 7 is a flowchart showing contents of a prediction process in the first embodiment;

FIG. 8 is an explanatory diagram showing a degree of deviation between a prediction model of the first embodiment and the measured values;

FIG. 9 is an explanatory diagram showing the degree of deviation between a prediction model of a comparative example and the measured values; and

FIG. 10 is a block diagram showing a configuration of an output voltage prediction system according to a second embodiment.

### DETAILED DESCRIPTION OF EMBODIMENTS

### A. First Embodiment

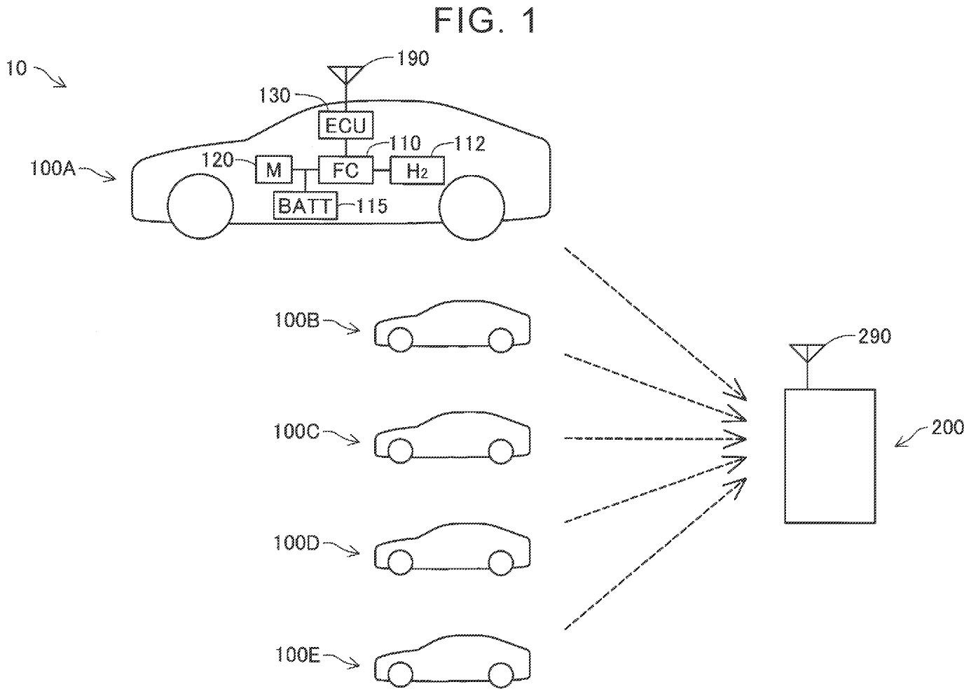

FIG. 1 is an explanatory view schematically showing a configuration of an output voltage prediction system 10 according to a first embodiment. The output voltage prediction system 10 includes a plurality of fuel cell vehicles 100A to 100E and an information processing device 200. FIG. 1 shows an output voltage prediction system 10 including five fuel cell vehicles 100A to 100E. The configurations of the fuel cell vehicles 100A to 100E are the same. The letters “A” to “E” added to the end of the symbols of the fuel cell vehicles 100A to 100E are added to distinguish the fuel cell vehicles 100A to 100E. When the fuel cell vehicles 100A to 100E are described without particular distinction, the fuel cell vehicles 100A to 100E will be described without the letters “A” to “E”. Note that, the number of fuel cell vehicles 100 included in the output voltage prediction system 10 is not limited to five, and may be, for example, several thousand or tens of thousands.

The fuel cell vehicle 100 includes a fuel cell 110, a hydrogen tank 112, a secondary battery 115, a traction motor 120, a control unit 130, and a vehicle communication device 190. The fuel cell vehicle 100 travels using the fuel cell 110 as a power source.

In the present embodiment, the fuel cell 110 is a solid polymer electrolyte fuel cell. The fuel cell 110 has a structure in which a plurality of single cells are laminated. The fuel cell 110 generates electricity by receiving supply of hydrogen gas stored in the hydrogen tank 112 and air taken in from the atmosphere. The fuel cell 110 is cooled by, for example, a refrigerant such as coolant. The electric power generated by the fuel cell 110 is supplied to the traction motor 120. The electric power generated by the fuel cell 110 may be charged to the secondary battery 115.

The traction motor 120 drives the fuel cell vehicle 100 using the electric power supplied from the fuel cell 110. The traction motor 120 may temporarily drive the fuel cell vehicle 100 using the electric power supplied from the secondary battery 115.

The control unit 130 is composed of an electronic control unit (ECU) of the fuel cell vehicle 100. The control unit 130 may be composed of one ECU or a plurality of ECUs. The control unit 130 controls each portion of the fuel cell vehicle 100, including power generation of the fuel cell 110. The control unit 130 communicates bidirectionally with the information processing device 200 via the vehicle communication device 190.

The information processing device 200 is installed in, for example, a management center that manages information on the fuel cell vehicles 100A to 100E. The information processing device 200 is configured as a computer including one or more processors, a storage device, and an input and output interface for inputting and outputting signals to and from the outside. The information processing device 200 includes a center communication device 290 that bidirectionally communicates with the vehicle communication device 190 of each of the fuel cell vehicles 100A to 100E.

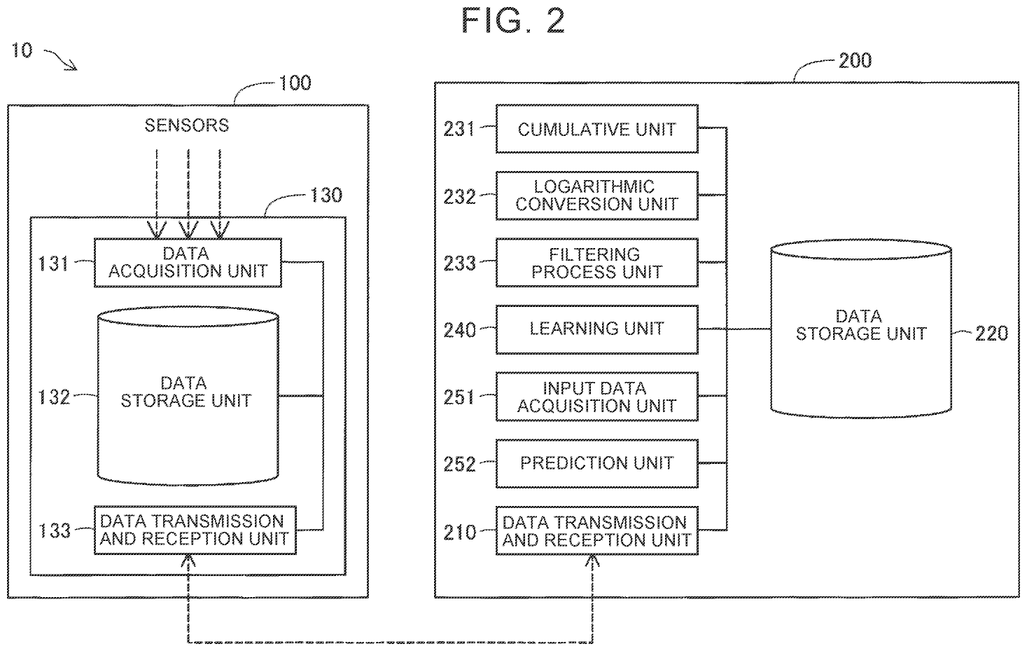

FIG. 2 is a block diagram showing a configuration of the output voltage prediction system 10 according to the present embodiment. The control unit 130 of the fuel cell vehicle 100 includes a vehicle data acquisition unit 131, a vehicle data storage unit 132, and a vehicle data transmission and reception unit 133. The vehicle data acquisition unit 131 and the vehicle data transmission and reception unit 133 are realized as software when the processor executes a program stored in the storage device of the control unit 130. The vehicle data storage unit 132 is provided in the storage device of the control unit 130.

The vehicle data acquisition unit 131 acquires time-series data in which the measured values measured by a plurality of sensors provided in the fuel cell vehicle 100 and the time when the measured values are measured are represented in time series. In the present embodiment, the sensors include a current sensor that measures the output current of the fuel cell 110 and a voltage sensor that measures the output voltage of the fuel cell 110. The sensors further include a sensor that measures the flow rate of hydrogen gas supplied to the fuel cell 110, a sensor that measures the pressure of the hydrogen gas, a sensor that measures the temperature of the hydrogen gas, a sensor that measures the flow rate of the air supplied to the fuel cell 110, a sensor that measures the pressure of the air, a sensor that measures the temperature of the air, and a sensor that measures the flow rate of the refrigerant supplied to the fuel cell 110, a sensor that measures the pressure of the refrigerant, and a sensor that measures the temperature of the refrigerant, and the like. In the present embodiment, the time-series data represents the moving average value of the measured values measured by these sensors.

In addition to the values measured by each sensor at each time, the time-series data includes the cumulative mileage of the fuel cell vehicle 100, the operating time of the fuel cell 110, the number of times of turning on and off the fuel cell 110, and the number of fluctuations in the output voltage of the fuel cell 110, at each time. The cumulative mileage is measured by an odometer provided in the fuel cell vehicle 100. The operating time of the fuel cell 110, the number of times of turning on and off the fuel cell 110, and the number of fluctuations in the output voltage are counted by the control unit 130. The time-series data represents identification information for identifying the fuel cell vehicle 100.

The vehicle data transmission and reception unit 133 transmits the time-series data acquired by the vehicle data acquisition unit 131 to the information processing device 200 via the center communication device 290. In the present embodiment, the time-series data acquired by the vehicle data acquisition unit 131 is immediately transmitted to the information processing device 200 by the vehicle data transmission and reception unit 133. The time-series data acquired by the vehicle data acquisition unit 131 may be stored in the vehicle data storage unit 132. In this case, the vehicle data transmission and reception unit 133 may transmit the time-series data stored in the vehicle data storage unit 132 to the information processing device 200 at a predetermined timing.

The information processing device 200 includes a center data transmission and reception unit 210, a center data storage unit 220, a cumulative unit 231, a logarithmic conversion unit 232, a filtering processing unit 233, a learning unit 240, an input data acquisition unit 251, and a prediction unit 252. The center data transmission and reception unit 210, the cumulative unit 231, the logarithmic conversion unit 232, the filtering processing unit 233, the learning unit 240, the input data acquisition unit 251, and the prediction unit 252 are realized as software when the processor executes the program stored in the storage device of the information processing device 200. The center data storage unit 220 is provided in the storage device of the information processing device 200. The learning unit 240 may be sometimes referred to as a relationship generation unit.

The center data transmission and reception unit 210 receives the time-series data transmitted from each of the fuel cell vehicles 100A to 100E via the center communication device 290. The center data storage unit 220 stores the time-series data received by the center data transmission and reception unit 210 for each of the fuel cell vehicles 100A to 100E.

The cumulative unit 231 converts a deterioration index amount, which will be described later, into a cumulative deterioration index amount that is a cumulative amount of the deterioration index amount. The logarithmic conversion unit 232 converts the cumulative deterioration index amount into a logarithm. The filtering processing unit 233 extracts data at a time that satisfies a predetermined condition from the time-series data.

The learning unit 240 executes a learning process of generating a prediction model for calculating a predicted value of the output voltage of the fuel cell 110. The prediction model shows the relationship between the logarithm of the cumulative deterioration index amount of the fuel cell 110 and the output voltage of the fuel cell 110 when the output current of the fuel cell 110 is within a predetermined current range. The prediction model is stored in the center data storage unit 220. The input data acquisition unit 251 acquires the input data input to the prediction model. The prediction unit 252 executes a prediction process of calculating a predicted value of the output voltage of the fuel cell 110 mounted on each of the fuel cell vehicles 100A to 100E using the prediction model. The contents of the learning process and the contents of the prediction process will be described later. The prediction result by the prediction unit 252 is transmitted to each of the fuel cell vehicle 100A to 100E by the center data transmission and reception unit 210.

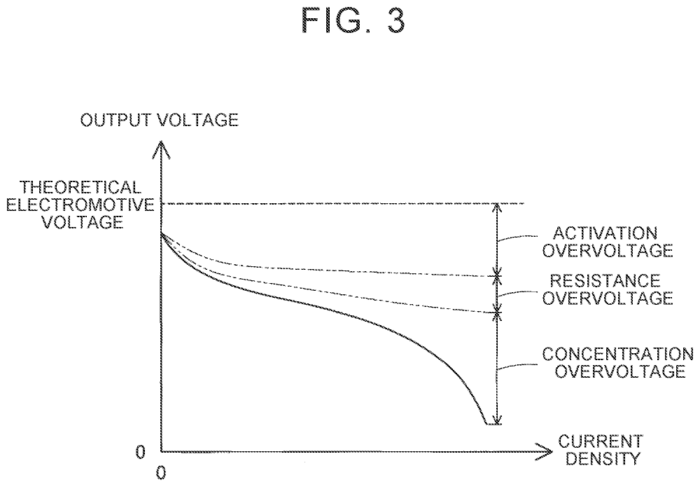

FIG. 3 is an explanatory diagram showing the relationship between the current density of a single cell of the fuel cell 110 and overvoltage. In FIG. 3, the horizontal axis represents the current density of the single cell, and the vertical axis represents the output voltage of the single cell. In FIG. 3, the theoretical electromotive voltage of a single cell is represented by a broken line. In general, as the current density becomes larger, the overvoltage becomes larger. Therefore, as shown by a solid line in FIG. 3, as the current density becomes larger, the output voltage becomes smaller. The overvoltage is composed of three elements: activation overvoltage, resistance overvoltage, and concentration overvoltage. In a solid polymer electrolyte fuel cell such as the fuel cell 110, the activation overvoltage is larger than the concentration overvoltage or the resistance overvoltage in the low current density region where the current density is relatively small.

When the fuel cell 110 deteriorates, the activation overvoltage becomes large. Deterioration of the fuel cell 110 means, for example, that a catalyst effective surface area becomes smaller due to elution of a catalyst of the fuel cell 110 or poisoning of the catalyst by carbon monoxide. The catalyst effective surface area is the surface area of a portion of the surface area of the catalyst that contributes to power generation. Deterioration of the fuel cell 110 progresses as the operating time of the fuel cell 110 becomes longer, the number of times of turning on and off the fuel cell 110 increases, and the number of fluctuations in the output voltage increases. Further, in the fuel cell 110 mounted on the fuel cell vehicle 100, as the mileage of the fuel cell vehicle 100 becomes longer, it becomes more likely that deterioration of the fuel cell 110 is progressing. The amount serving as an index of the degree of progress of deterioration of the fuel cell 110, such as the mileage of the fuel cell vehicle 100, the operating time of the fuel cell 110, the number of times of turning on and off the fuel cell 110, and the number of fluctuations in the output voltage of the fuel cell 110, is referred to as the deterioration index amount.

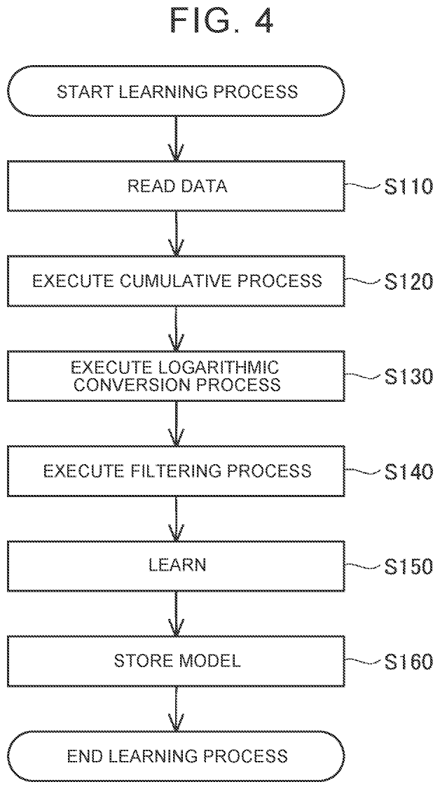

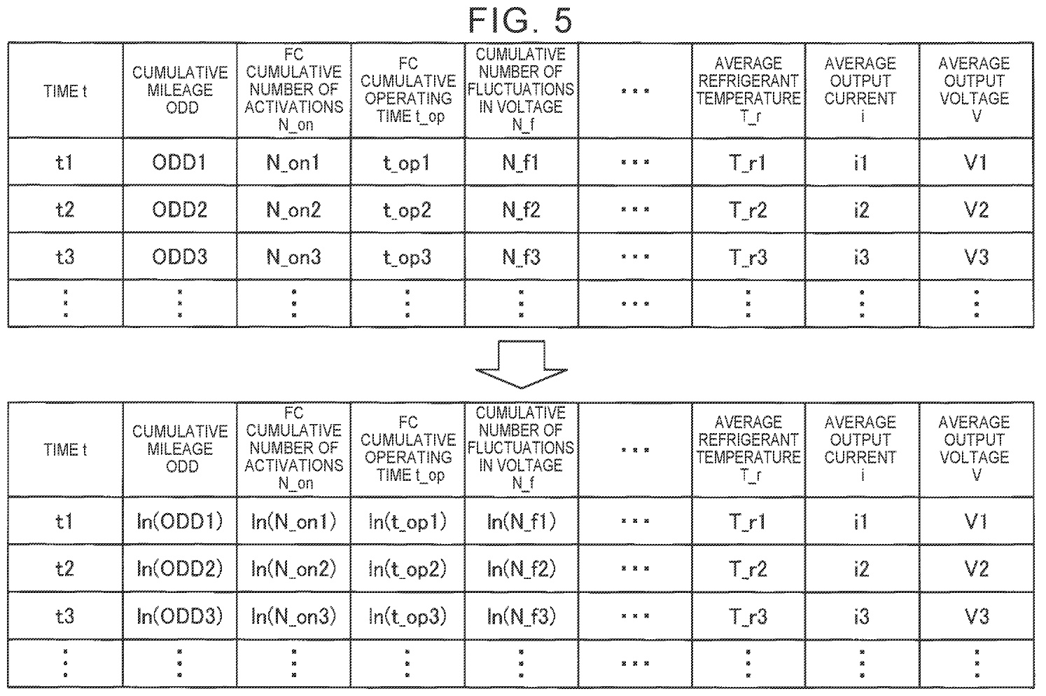

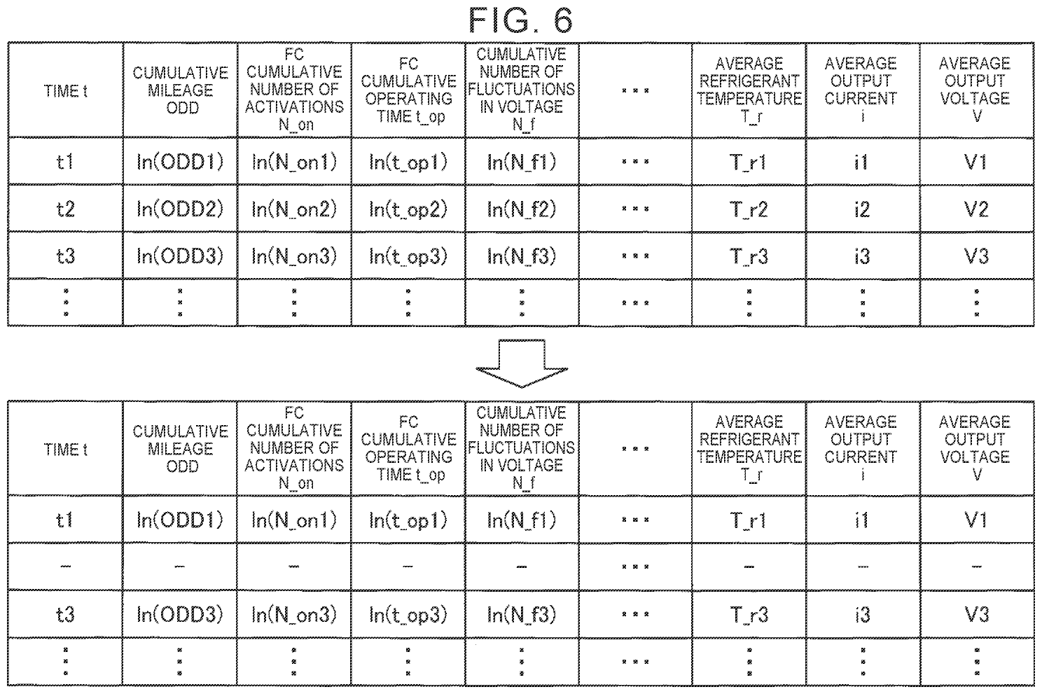

FIG. 4 is a flowchart showing the contents of the learning process in the present embodiment. FIG. 5 is an explanatory diagram schematically showing time-series data before and after the logarithmic conversion process. FIG. 6 is an explanatory diagram schematically showing time-series data before and after the filtering process. The learning process is started by the information processing device 200 when a predetermined start command is supplied to the information processing device 200. The start command is supplied to the information processing device 200 at a predetermined timing. In the present embodiment, the information processing device 200 is supplied with the start command at a monthly cycle.

First, in step S110, the cumulative unit 231 reads the time-series data of each of the fuel cell vehicles 100A to 100E stored in the center data storage unit 220. Next, in step S120, the cumulative unit 231 executes a cumulative process of converting the deterioration index amount represented in the time-series data of each of the fuel cell vehicles 100A to 100E into the cumulative deterioration index amount that is the cumulative amount of the deterioration index amount. At this time, the cumulative unit 231 does not accumulate the deterioration index amount that is already represented as the cumulative amount among the deterioration index amounts. For example, the cumulative mileage of the fuel cell vehicle 100 has already been represented as the cumulative amount. Therefore, the cumulative unit 231 does not accumulate the cumulative mileage. The time-series data processed in the cumulative process is transmitted to the logarithmic conversion unit 232.

In step S130, the logarithmic conversion unit 232 executes a logarithmic conversion process of converting, into the logarithm, the cumulative deterioration index amount represented in the time-series data of each of the fuel cell vehicles 100A to 100E processed in the cumulative process. In the present embodiment, the logarithmic conversion unit 232 converts the cumulative deterioration index amount into a natural logarithm of the cumulative deterioration index amount, as shown in FIG. 5. The logarithmic conversion unit 232 may convert the cumulative deterioration index amount into a common logarithm of the cumulative deterioration index amount. The time-series data processed in the logarithmic conversion process is transmitted to the filtering processing unit 233.

In step S140, the filtering processing unit 233 executes the filtering process of extracting data at a time that satisfies a predetermined condition from the time-series data of each of the fuel cell vehicles 100A to 100E processed in the logarithmic conversion process. In the present embodiment, the filtering processing unit 233 extracts, from the time-series data, data at a time that satisfies the condition that the output current of the fuel cell 110 is within a predetermined current range. The above-mentioned current range is determined in a range in which the ratio of the activation overvoltage to the overvoltage of the fuel cell 110 exceeds a predetermined ratio. The ratio mentioned above is at least 50%. In the present embodiment, the filtering processing unit 233 may extract, from the time-series data, data at a time that satisfies the condition that the output current of the fuel cell 110 is within a predetermined current range and also satisfies other conditions. For example, the filtering processing unit 233 may extract data at a time that satisfies the condition that the output current of the fuel cell 110 is within the predetermined current range and the flow rate of the fuel gas is within the predetermined flow rate range. As an example, FIG. 6 shows how the data at time t1 and the data at time t3 that satisfy the above-mentioned condition are extracted from the data from time tl to time t3 for the fuel cell vehicle 100A. The filtering processing unit 233 transmits the time-series data processed in the filtering process, that is, the time-series data representing the data at a time that satisfies the above-mentioned condition, to the learning unit 240. Note that, the order of the process in step S130 and the process in step S140 may be reversed. That is, the logarithmic conversion process may be executed on the time-series data processed in the filtering process after the filtering process is executed on the time-series data processed in the cumulative processing.

In step S150, the learning unit 240 generates the prediction model by reading the time-series data of each of the fuel cell vehicles 100A to 100E processed in the filtering process and executing the machine learning. The prediction model is represented as a linear function with any one of the logarithms of a plurality of the cumulative deterioration index amounts as the explanatory variable and the output voltage as the objective variable.

In the present embodiment, the algorithm of machine learning executed by the learning unit 240 is linear regression. More specifically, the algorithm of machine learning executed by the learning unit 240 is the Elastic Net. The algorithm of machine learning executed by the learning unit 240 is not limited to the Elastic Net, and may be, for example, the Lasso regression. In the Elastic Net and the Lasso regression, the weight of the logarithm of the cumulative deterioration index amount with a low contribution can be set to zero among the logarithms of the cumulative deterioration index amounts that are input by the function of the regularization term. Therefore, it is possible to enter the logarithms of the cumulative deterioration index amounts that are possibly the explanatory variables. Note that, when the logarithm of the cumulative deterioration index amount included in the time-series data is one, the algorithm of machine learning may be the ridge regression.

In the present embodiment, the learning unit 240 generates a prediction model common to the fuel cell vehicles 100A to 100E using the time-series data of each of the fuel cell vehicles 100A to 100E. Note that, the learning unit 240 may generate a plurality of the prediction models for each of the fuel cell vehicles 100A to 100E. For example, the learning unit 240 may generate the prediction model for the fuel cell vehicle 100A using the time-series data of the fuel cell vehicle 100A, and may generate the prediction model for the fuel cell vehicle 100B using the time-series data of the fuel cell vehicle 100B.

In step S160, the learning unit 240 stores the prediction model in the center data storage unit 220. After that, the learning unit 240 ends this process. In the present embodiment, the information processing device 200 starts this process again after one month. New information is transmitted from each of the fuel cell vehicles 100A to 100E during one month, whereby new information is added to the time-series data stored in the center data storage unit 220. A new prediction model is generated by the learning process executed one month later, and the prediction model stored in the center data storage unit 220 is updated.

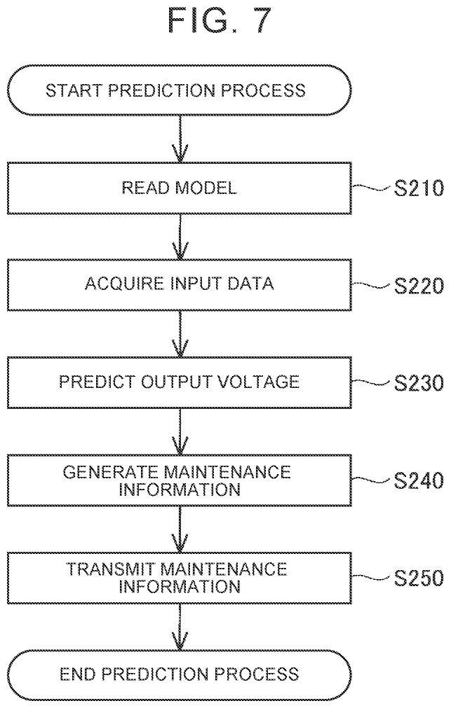

FIG. 7 is a flowchart showing the contents of the prediction process in the present embodiment. The prediction process is started by the information processing device 200 when a predetermined start command is supplied to the information processing device 200. The start command is supplied to the information processing device 200 at a predetermined timing. In the present embodiment, the information processing device 200 is supplied with the start command at a monthly cycle, that is, when the prediction model is updated. The prediction process may be sometimes referred to as an output voltage prediction method.

First, in step S210, the prediction unit 252 reads the prediction model stored in the center data storage unit 220. Next, in step S220, the input data acquisition unit 251 acquires the input data input to the prediction model. The input data includes the cumulative deterioration index amount of the fuel cell 110 mounted on each of the fuel cell vehicles 100A to 100E. The input data acquisition unit 251 calculates an estimated value of the cumulative deterioration index amount of the fuel cell 110 after a lapse of a predetermined period based on the relationship between the time calculated using the time-series data and the cumulative deterioration index amount, and acquires the estimated value as input data. For example, the input data acquisition unit 251 calculates an increase amount of the cumulative deterioration index amount per day using the cumulative deterioration index amount at the latest time represented in the time-series data and the cumulative deterioration index amount at a time one month prior to the latest time, and calculates the estimated value of the cumulative deterioration index amount of the fuel cell 110 after one month using the increase amount. When the increasing tendency of the cumulative deterioration index amount is non-uniform, the input data acquisition unit 251 may calculate the estimated value of the cumulative deterioration index amount so as to maximize the estimated value of the cumulative deterioration index amount. The input data further includes the output current of the fuel cell 110 mounted on each of the fuel cell vehicles 100A to 100E, the flow rate of hydrogen gas supplied to the fuel cell 110, and the like. Except for the logarithm of the cumulative deterioration index amount, a value satisfying the same condition as that used in the filtering process shown in step S140 in FIG. 6 is used as the input data.

In step S230, the prediction unit 252 calculates the predicted value of the output voltage of the fuel cell 110 under the condition represented by the input data using the input data and the prediction model. In the present embodiment, the prediction unit 252 converts the cumulative deterioration index amount of the fuel cell 110 represented in the input data into the logarithm, applies the logarithm of the cumulative deterioration index amount to the prediction model, and calculates the predicted value of the output voltage of the fuel cell 110 under the condition represented by the input data. The predicted value of the output voltage of the fuel cell 110 mounted on each of the fuel cell vehicles 100A to 100E is calculated. Note that, the prediction unit 252 may predict the time when the output voltage becomes equal to or lower than a predetermined threshold value using the prediction model.

In step S240, the prediction unit 252 generates maintenance information indicating whether maintenance of the fuel cell 110 is required, etc., using the predicted value of the output voltage of the fuel cell 110 and outputs the maintenance information. When the predicted value of the output voltage of the fuel cell 110 is equal to or lower than a predetermined threshold value, the maintenance information indicates that the maintenance of the fuel cell 110 is required. When the predicted value of the output voltage of the fuel cell 110 exceeds the predetermined threshold value, the maintenance information indicates that the maintenance of the fuel cell 110 is not required. In the present embodiment, the prediction unit 252 generates the maintenance information for each of the fuel cell vehicles 100A to 100E, and transmits the generated maintenance information corresponding to each of the fuel cell vehicles 100A to 100E to each of the fuel cell vehicles 100A to 100E. After that, the prediction unit 252 ends this process. The maintenance information transmitted to each of the fuel cell vehicles 100A to 100E is displayed on the on-board monitor provided in each of the fuel cell vehicles 100A to 100E.

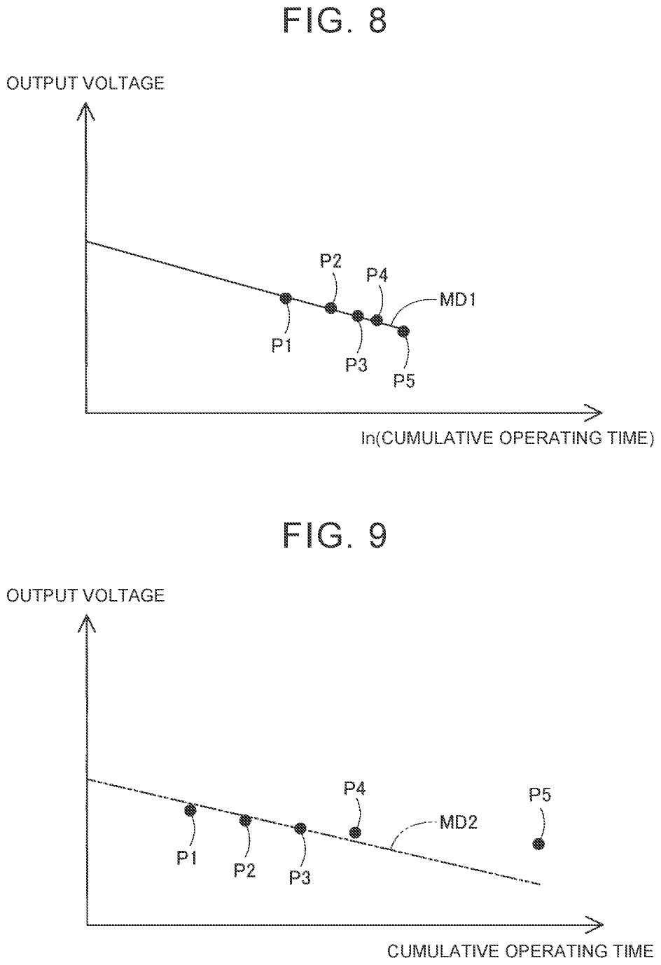

FIG. 8 is an explanatory diagram showing the degree of deviation between the prediction model MD1 in the present embodiment and the measured values. In FIG. 8, the horizontal axis represents the logarithm of the cumulative operating time of the fuel cell 110, and the vertical axis represents the output voltage of the fuel cell 110. In FIG. 8, a prediction model MD1 having the logarithm of the cumulative operating time as the explanatory variable and the output voltage as the objective variable is shown by a solid line.

An output voltage V of the fuel cell 110 is represented by the following equation (1) using the Tafel equation. In the following equation (1), V₀ is the open circuit voltage, A is the constant, i_{cat} is the current density per catalyst surface area, and i₀ is the exchange current density.

V=V₀−A×1n (i_{cat}/i₀) (1)

The relationship between an output current i of the fuel cell 110 measured by the current sensor provided in the fuel cell vehicle 100 and a current density i_{cat} per surface area of the catalyst is represented by the following equation (2). In the equation (2) below, S is the electrochemically effective surface area of the catalyst, that is, the surface area of the portion of the surface area of the catalyst that contributes to power generation.

i=S×i_{cat} (2)

The relationship between the electrochemically effective surface area S of the catalyst and a cumulative deterioration index amount P is represented by the following equation (3). In the following equation (3), C1 and C2 are constants. The relationship between the electrochemically effective surface area S of the catalyst and the cumulative deterioration index amount P can be confirmed, for example, by a test using cyclic voltammetry.

1n(S)=C1−C2×1n (P) (3)

The following equation (4) can be obtained by rearranging the equations (1) to (3) and eliminating i_{cat} and S. In the following equation (4), V₀, A, (i/i₀), C1 and C2 are constants.

V=V₀−A×1n (i/i₀)+A×(C1−C2×1n (P)) (4)

In FIG. 8, measured values P1 to P5 of the output voltage are shown by circles. The measured values P1 to P4 are the measured values used in the learning process of generating the prediction model MD1, and the measured value P5 is the measured value measured to confirm the degree of deviation between the prediction model MD1 and the measured values. From the equation (4), the relationship between the logarithm of the cumulative deterioration index amount P and the output voltage V is linear. Therefore, the predicted value by the prediction model MD1 and the measured value P5 are almost consistent.

FIG. 9 is an explanatory diagram showing the degree of deviation between the prediction model MD2 and the measured values in a comparative example. In FIG. 9, the horizontal axis represents the cumulative operating time of the fuel cell 110, and the vertical axis represents the output voltage of the fuel cell 110. In FIG. 9, as the comparative example, the prediction model MD2 when the logarithmic conversion process is not executed in the learning process is shown by a chain double-dashed line. In FIG. 9, the measured values P1 to P5 of the output voltage that are the same as those in FIG. 8 are shown by circles. The relationship between the cumulative deterioration index amount P and the output voltage V is non-linear. Therefore, the degree of deviation between the predicted value of the output voltage by the prediction model MD2 and the measured value P5 in the comparative example is larger than the degree of deviation between the predicted value of the output voltage by the prediction model MD1 and the measured value P5 in the present embodiment.

According to the output voltage prediction system 10 in the present embodiment described above, the prediction unit 252 predicts the output voltage of the fuel cell 110 using the prediction model that represents the relationship between the logarithm of the cumulative deterioration index amount of the fuel cell 110 and the output voltage as a linear function. As described above, in the present embodiment, the relationship between the logarithm of the cumulative deterioration index amount of the fuel cell 110 and the output voltage is linear. Therefore, the output voltage of the fuel cell 110 can be predicted accurately using the prediction model. In particular, in the fuel cell 110 mounted on the fuel cell vehicle 100 as in the present embodiment, the ratio of the activation overvoltage to the overvoltage tends to be large, and the relationship between the logarithm of the cumulative deterioration index amount and the output voltage becomes linear. Therefore, the output voltage of the fuel cell 110 can be predicted accurately using the prediction model as described above.

Further, in the present embodiment, the mileage of the fuel cell vehicle 100, the operating time of the fuel cell 110, the number of times of turning on and off the fuel cell 110, and the number of fluctuations in the output voltage of the fuel cell 110 are used as the deterioration index amounts. Any of the values above has a correlation with a decrease in the output voltage of the fuel cell 110. Therefore, the output voltage of the fuel cell 110 can be predicted accurately.

Further, in the present embodiment, the learning unit 240 generates the prediction model using time-series data acquired from the fuel cell vehicles 100A to 100E. Therefore, the output voltage of the fuel cell 110 can be predicted accurately. In particular, in the present embodiment, the learning unit 240 generates the prediction model by machine learning. Therefore, the prediction accuracy of the output voltage of the fuel cell 110 can be enhanced.

### B. Second Embodiment

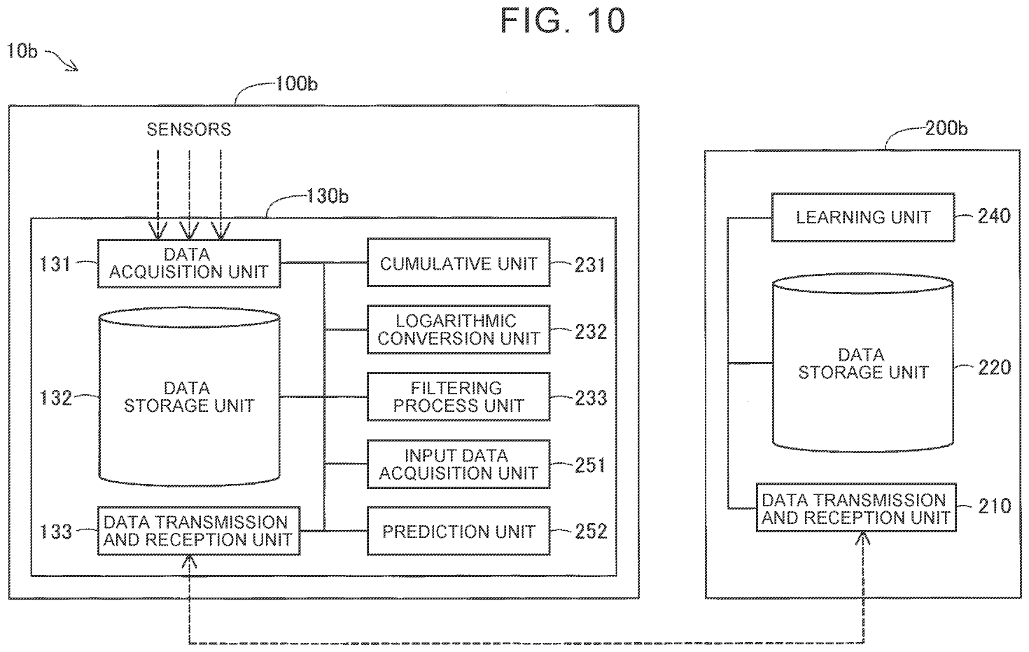

FIG. 10 is a block diagram showing a configuration of an output voltage prediction system 10b according to a second embodiment. In the second embodiment, the cumulative unit 231, the logarithmic conversion unit 232, the filtering processing unit 233, the input data acquisition unit 251 and the prediction unit 252 are provided in a control unit 130b of a fuel cell vehicle 100b instead of an information processing device 200b, which is different from the configuration of the first embodiment. Other configurations are the same as those in the first embodiment unless otherwise described.

In the present embodiment, the control unit 130b of each fuel cell vehicle 100b includes the vehicle data acquisition unit 131, the vehicle data storage unit 132, the vehicle data transmission and reception unit 133, the cumulative unit 231, the logarithmic conversion unit 232, the filtering processing unit 233, the input data acquisition unit 251 and the prediction unit 252. Prior to transmission of the time-series data to the information processing device 200b, the cumulative unit 231 executes the cumulative process, the logarithmic conversion unit 232 executes the logarithmic conversion process, and the filtering processing unit 233 executes the filtering process. The vehicle data transmission and reception unit 133 transmits the time-series data after the filtering process to the information processing device 200b.

The information processing device 200b includes the center data transmission and reception unit 210, the center data storage unit 220, and the learning unit 240. The center data transmission and reception unit 210 receives the time-series data processed in the filtering process from each fuel cell vehicle 100b and stores the data in the center data storage unit 220. The learning unit 240 executes the learning process to generate the prediction model. In the present embodiment, the cumulative process, the logarithmic conversion process, and the filtering process are not executed in the learning process. The center data transmission and reception unit 210 transmits the prediction model to each fuel cell vehicle 100b. The prediction model is stored in the vehicle data storage unit 132 of each fuel cell vehicle 100b.

In the present embodiment, the prediction process is executed by the control unit 130b of each fuel cell vehicle 100b. The time-series data stored in the vehicle data storage unit 132 includes the latest information measured after the prediction model is generated. The input data acquisition unit 251 calculates an estimated value of the cumulative deterioration index amount of the fuel cell 110 after, for example, one month based on the relationship between the time calculated using the time-series data stored in the vehicle data storage unit 132 and the cumulative deterioration index amount, and acquires the estimated value as the input data. The prediction unit 252 calculates the predicted value of the output voltage of the fuel cell 110 under the condition represented by the input data using the input data and the prediction model. The prediction unit 252 displays the maintenance information corresponding to the predicted value of the output voltage of the fuel cell 110 on the on-board monitor of the fuel cell vehicle 100b.

According to the output voltage prediction system 10b in the present embodiment described above, the fuel cell vehicle 100b can execute the prediction process with the control unit 130b of the own vehicle using the prediction model received from the information processing device 200b. Therefore, the output voltage can be predicted using the latest information about the own vehicle.

Further, in the present embodiment, the fuel cell vehicle 100b transmits the time-series data processed in the filtering process to the information processing device 200b. Therefore, the amount of time-series data transmitted from the fuel cell vehicle 100b to the information processing device 200b can be reduced.

### C. Other Embodiments:

(C1) In the output voltage prediction systems 10, 10b according to each of the above-described embodiments, the fuel cell vehicles 100, 100b are each provided with the voltage sensor that measures the output voltage of the fuel cell 110, and acquires the output voltage of the fuel cell 110 by measuring the output voltage of the fuel cell 110 using the voltage sensor. On the other hand, the fuel cell vehicles 100, 100b do not have to include the voltage sensor that measures the output voltage of the fuel cell 110. In this case, the fuel cell vehicles 100, 100b may acquire the output voltage of the fuel cell 110 by estimation.

For example, the control units 130, 130b can estimate the output voltage of the fuel cell 110 using the following equation (5). In the following equation (5), Q represents the heat generation amount of the fuel cell 110, i represents the output current of the fuel cell 110, E₀ represents the theoretical electromotive force of the fuel cell 110, and V represents the output voltage of the fuel cell 110.

Q=i×E₀−V (5)

When the fuel cell 110 deteriorates, the heat generation amount Q of the fuel cell 110 increases. The heat generation amount Q can be estimated using the measured value of the temperature sensor that measures the temperature of the refrigerant supplied to the fuel cell 110, the measured value of the outside air temperature measured by the outside air temperature sensor provided in the fuel cell vehicle 100, and the measured value of the vehicle speed measured by the vehicle speed sensor provided in the fuel cell vehicle 100. The output current i can be measured by the current sensor provided in the fuel cell vehicle 100. The theoretical electromotive force is a predetermined constant. It is also possible to estimate the output voltage of the fuel cell 110 using cyclic voltammetry. When the fuel cell 110 deteriorates, the output current measured by the current sensor when a triangular wave of voltage is applied to the fuel cell 110 decreases. The relationship between the output current and the output voltage can be obtained by a test conducted in advance, and the output voltage of the fuel cell 110 can be estimated using the relationship and the output current when the triangular wave of the voltage is applied to the fuel cell 110.

(C2) In the output voltage prediction systems 10, 10b according to each of the above-described embodiments, the learning unit 240 generates the prediction model representing a linear function of the logarithm of the cumulative deterioration index amount and the output voltage by machine learning. On the other hand, the learning unit 240 may acquire a linear function of the logarithm of the cumulative deterioration index amount and the output voltage without using machine learning. Further, for example, a map or a linear function representing the relationship between the logarithm of the cumulative deterioration index amount and the output voltage, which is created by a test conducted in advance, may be stored in the center data storage unit 220 of the information processing device 200 or the vehicle data storage unit 132 of the fuel cell vehicle 100b, and the prediction unit 252 provided in the information processing device 200 or the prediction unit 252 provided in the fuel cell vehicle 100b may calculate the predicted value of the output voltage using the map or the linear function as described above.

(C3) In the output voltage prediction system 10b according to the second embodiment described above, the logarithmic conversion unit 232 provided in the fuel cell vehicle 100b executes the logarithmic conversion process of the time-series data. On the other hand, the logarithmic conversion unit 232 may be provided in the information processing device 200b instead of being provided in the fuel cell vehicle 100b. Even in this case, the filtering processing unit 233 provided in the fuel cell vehicle 100b can execute the filtering process in the fuel cell vehicle 100b. Therefore, the amount of the time-series data transmitted from the fuel cell vehicle 100b to the information processing device 200b can be reduced.

(C4) In the output voltage prediction systems 10, 10b according to each of the above-described embodiments, the fuel cell vehicles 100, 100b each include the vehicle communication device 190. On the other hand, the fuel cell vehicles 100, 100b do not have to include the vehicle communication device 190. In this case, for example, a diagnostics device including a communication device that bidirectionally communicates with the information processing devices 200, 200b may be connected to the control units 130, 130b of the fuel cell vehicles 100, 100b, and the control units 130, 130b may transmit and receive the time-series data and the prediction model via the communication device.

(C5) The output voltage prediction systems 10, 10b according to each of the above-described embodiments include the fuel cell vehicles 100A to 100E. On the other hand, the number of fuel cell vehicles 100 included in the output voltage prediction systems 10, 10b may be one. In this case, the fuel cell vehicle 100 may be provided with the learning unit 240 and the prediction unit 252.

(C6) The output voltage prediction systems 10, 10b according to each of the above-described embodiments include the fuel cell vehicles 100, 100b and the information processing devices 200, 200b. On the other hand, the output voltage prediction systems 10, 10b may include a ship sailing using the fuel cell 110 as a power source and an aircraft flying using the fuel cell 110 as a power source, instead of the fuel cell vehicles 100, 100b.

The present disclosure is not limited to the embodiments above, and can be implemented with various configurations without departing from the scope of the present disclosure. For example, the technical features of the embodiments corresponding to the technical features in each mode described in the section of the summary may be replaced or combined appropriately to solve some or all of the above issues or to achieve some or all of the above effects. When the technical features are not described as essential in the present specification, the technical features can be deleted as appropriate.

What is claimed is:

1. An output voltage prediction system for a fuel cell, comprising:
a storage unit that stores a relationship between a logarithm of a cumulative deterioration index amount and an output voltage of the fuel cell when an output current of the fuel cell is within a predetermined current range, the cumulative deterioration index amount being a cumulative amount of a deterioration index amount related to progress of deterioration of the fuel cell;
an input data acquisition unit that acquires the cumulative deterioration index amount of the fuel cell as input data; and
a prediction unit that converts the input data acquired by the input data acquisition unit into a logarithm and predicts the output voltage of the fuel cell based on the logarithm of the input data and the relationship stored in the storage unit.

2. The output voltage prediction system according to claim 1, wherein the deterioration index amount is any one of an operating time of the fuel cell, the number of times of turning on and off power generation of the fuel cell, and the number of fluctuations in the output voltage of the fuel cell.

3. The output voltage prediction system according to claim 1, wherein the current range is a range in which a ratio of activation overvoltage to overvoltage of the fuel cell exceeds 50%.

4. The output voltage prediction system according to claim 1, further comprising:
a data acquisition unit that acquires time-series data in which the deterioration index amount or the cumulative deterioration index amount of the fuel cell, the output current of the fuel cell, and the output voltage of the fuel cell are represented in time series; and
a relationship generation unit that generates the relationship using the time-series data and stores the relationship in the storage unit.

5. The output voltage prediction system according to claim 4, wherein the relationship generation unit generates the relationship by machine learning.

6. The output voltage prediction system according to claim 1, wherein the fuel cell supplies electric power to a traction motor of a fuel cell vehicle.

7. An output voltage prediction method for a fuel cell, comprising:
a step of storing, in a storage unit, a relationship between a logarithm of a cumulative deterioration index amount and an output voltage of the fuel cell when an output current of the fuel cell is within a predetermined current range, the cumulative deterioration index amount being a cumulative amount of a deterioration index amount related to progress of deterioration of the fuel cell;
a step of acquiring the cumulative deterioration index amount of the fuel cell as input data; and
a step of converting the input data into a logarithm and predicting the output voltage of the fuel cell based on the logarithm of the input data and the relationship stored in the storage unit.
